(19) United States
(12) Patent Application Publication
(10) Pub. No.: US 2014/0250658 A1
(43) Pub. Date: Sep. 11, 2014

(54) VACUUM CHAMBERS AND COMPONENTS FOR SEMICONDUCTOR SUBSTRATE PROCESSING AND METHODS OF FABRICATION

(71) Applicant: APPLIED MATERIALS, INC., Santa Clara, CA (US)

(72) Inventor: KEITH A. MILLER, Mountain View, CA (US)

(73) Assignee: APPLIED MATERIALS, INC., Santa Clara, CA (US)

(21) Appl. No.: 13/785,122

(22) Filed: Mar. 5, 2013

(51) Int. Cl. H01L 21/02

(52) U.S. Cl. CPC H01L 21/02
USPC 29/428

(57) ABSTRACT

Embodiments of methods for fabricating a vacuum chamber for semiconductor substrate processing are provided herein. In some embodiments, a method for fabricating a vacuum chamber for semiconductor substrate processing may include: providing one or more plates of material that together form a desired shape of a body of the vacuum chamber; performing a friction stir weld on outer surfaces of adjacent ends of the one or more plates to form the body of the vacuum chamber; and coupling at least one of a top or bottom to a respective top or bottom of the body to form the vacuum chamber.

### FIELD

Embodiments of the present invention generally relate to semiconductor processing equipment.

### BACKGROUND

Vacuum chambers utilized for semiconductor substrate processing are typically fabricated by machining a solid block of metal or welding a plurality of metal plates together. However, the inventor has observed that machining a solid block of metal to create a vacuum chamber is a costly and inefficient process due to the size of the block of material needed to create a chamber of a practical size, and the waste created by machining the block. In addition, the inventor has also observed that conventional welding processes used to fabricate vacuum chambers (e.g., Arc welding or TIG welding) often produce defects and leaks, making the vacuum chamber structurally insufficient or incapable of maintaining a vacuum environment within the chamber.

Therefore, the inventors have provided embodiments of vacuum chambers for semiconductor substrate processing and components for use therein.

### SUMMARY

Embodiments of vacuum chambers for semiconductor substrate processing and components for use therein are provided herein. In some embodiments, a method for fabricating a vacuum chamber for semiconductor substrate processing may include: providing one or more plates of material that together form a desired shape of a body of the vacuum chamber; performing a friction stir weld on outer surfaces of adjacent ends of the one or more plates to form the body of the vacuum chamber; and coupling at least one of a top or bottom to a respective top or bottom of the body to form the vacuum chamber.

In some embodiments, a method for fabricating a vacuum chamber component for use in a vacuum process chamber includes providing one or more plates of material that together form a desired shape of a body of the vacuum chamber component; performing a friction stir weld on outer surfaces of adjacent ends of the one or more plates to form the body of the vacuum chamber component; and coupling a mounting flange to a top of the body to form the vacuum chamber component.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a method for fabricating a vacuum chamber for semiconductor substrate processing in accordance with some embodiments of the present invention.

FIGS. 2-5 depict a vacuum chamber in various stages of fabrication of a vacuum chamber for semiconductor substrate processing in accordance with some embodiments of the present invention.

FIG. 6 depicts a portion of a vacuum chamber body and a top or bottom of the vacuum chamber coupled to the vacuum chamber body in accordance with some embodiments of the present invention.

FIG. 7 depicts a portion of a vacuum chamber body and a top or bottom of the vacuum chamber coupled to the vacuum chamber body in accordance with some embodiments of the present invention.

FIG. 8 depicts a top view of a fabricated vacuum chamber in accordance with some embodiments of the present invention.

FIG. 9 depicts a top view of a fabricated vacuum chamber in accordance with some embodiments of the present invention.

FIG. 10 depicts a cross sectional side view of a fabricated vacuum chamber component in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of methods for fabricating a vacuum chamber or component for use in a process chamber for semiconductor substrate processing are provided herein. In at least some embodiments, the inventive method may advantageously facilitate the fabrication of vacuum chambers and components having fewer defects, lower porosity at points of coupling (weld seams) and improved structural integrity as compared to conventionally used vacuum chamber fabrication methods. In addition, embodiments of the inventive method may be less costly and produce less waste, as compared to conventionally used vacuum chamber fabrication methods.

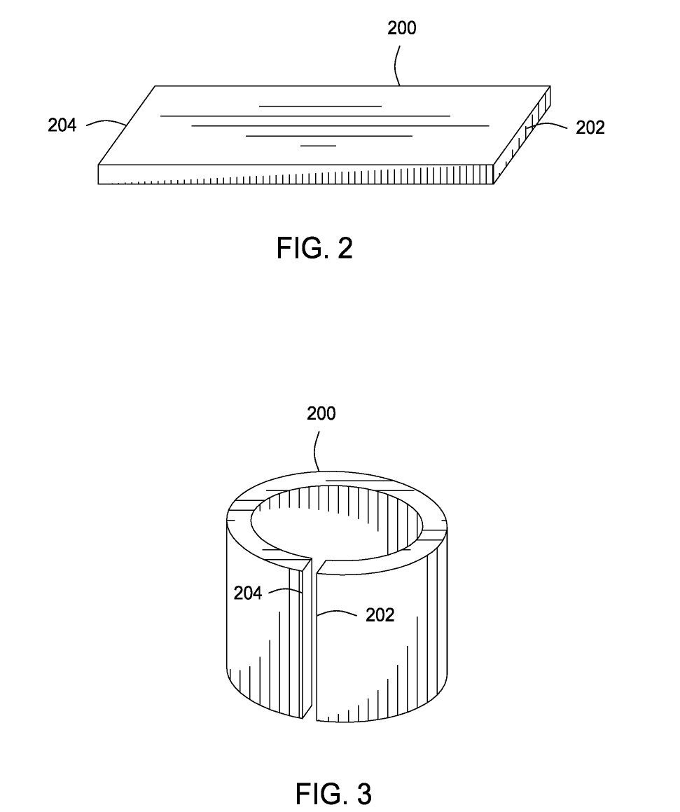

The method 100 generally begins at 101 where one or more plates of material that together form a desired shape of a body of the vacuum chamber or component are provided. For example, a plate of material (plate 200) is shown in FIG. 2. The plate 200 may be fabricated from any process compatible material suitable to form a body of a vacuum chamber, for example, a metal such as stainless steel, aluminum or aluminum alloys, or the like. In addition, the plate 200 may be of any shape to form a vacuum chamber or component body of a desired shape. For example, in some embodiments, the plate 200 may have a rectangular cross sectional shape (e.g., such as shown in FIG. 2) to form a cylindrical vacuum chamber or component body. Alternatively, in some embodiments, the plate 200 may have other cross sectional shapes, for example a trapezoidal shape, to form a conical vacuum chamber or component body. Although shown as a regular geometric shape, the plate 200 may be an irregular shape to facilitate forming a vacuum chamber or component having desired internal or external features.

The plate 200 may have any dimensions suitable to form a vacuum chamber body or component of a desired size. For example, the plate 200 may have a thickness suitable to sustain desired vacuum pressures during use, such as, for example, between about 0.5 to about 2.0 inches. In embodiments where the plate 200 has a rectangular cross section, the plate 200 may have a length (distance between a first end 202 and a second end 204) and a width suitable to provide an internal volume suitable to enclose the substrate support and any other chamber components, as desired or required for a particular application. For example, in some embodiments, the plate of material may have a length of about 20 to about 120 inches. In some embodiments, the plate of material may have a width of about 20 to about 120 inches The exact size may vary on the desired substrate to be processed, for example, 200 mm, 300 mm, or 450 mm diameter semiconductor substrates, flat panels for LCD or solar cell applications, such as square panels between about 1 to about 3 meters per side, or the like.

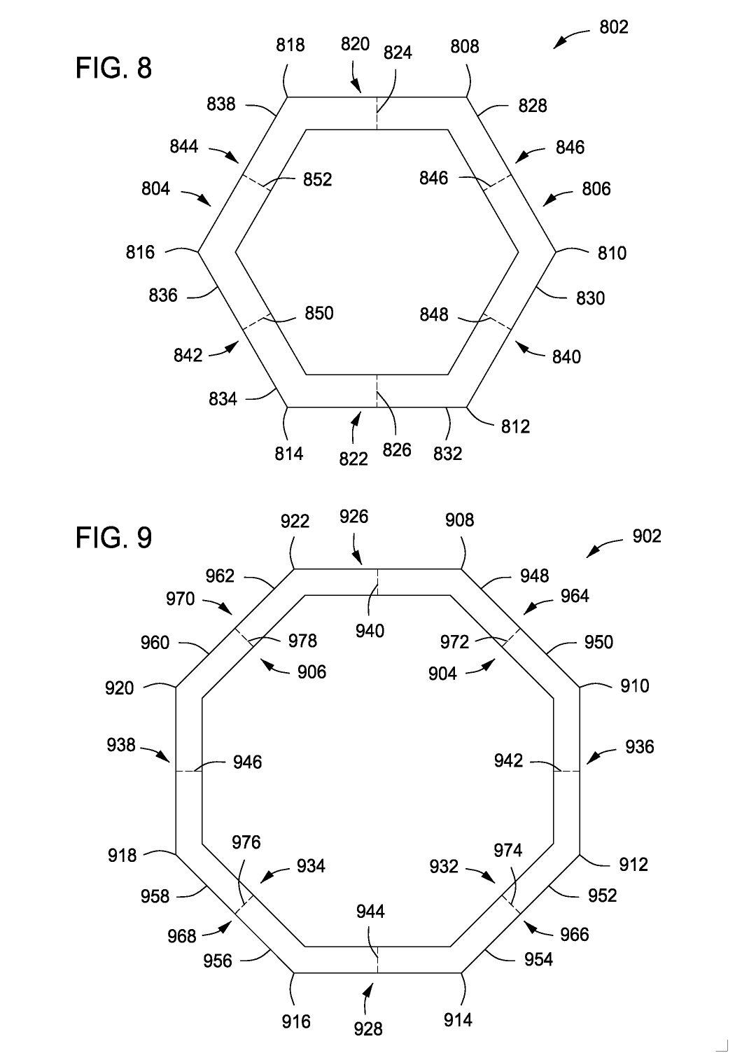

Although only one plate 200 is shown, any number of plates 200 may be provided to form a vacuum chamber or component having a desired shape. For example, in some embodiments, two or more plates 200, such as two, six, or eight plates may be provided. For example, such as described below with respect to FIG. 8 (e.g., two or six plates) and FIGS. 9 (four or eight plates). Other numbers of plates may also be used as desired.

In some embodiments, the one or more plates 200 may be provided in the desired form, or may be bent into a desired shape to facilitate forming the body of the vacuum chamber or component . For example, at 102, a plate of material (plate) 200 to be bent into a desired shape to form a vacuum chamber or component body may be provided, such as the flat plate 200 shown in FIG. 2. At 104, the plate 200 may be bent to form a desired shape, such as the cylinder shown in FIG. 3. The plate 200 may be bent via any suitable process, such as press bending, roll bending, or the like, to form the desired shape. The shape may be any shape suitable to form a suitable vacuum chamber or component body. For example, in some embodiments, the plate 200 may be bent such that the first end 202 of the plate 200 is disposed proximate the second end 204 of the plate 200 to form a cylindrical body, such as shown in FIG. 3. Alternatively, in some embodiments, the shape may be hexagonal or octagonal such as described below with respect to FIGS. 8 and 9. Other geometric shapes, such as rectangular, square, other regular or irregular polygonal shapes, or the like. Although shown as regular geometric shapes, the plate 200 may be bent in any manner to form irregular shapes to form a vacuum chamber or component having desired internal or external features. In some embodiments, flat plates may be provided and joined together without any bending of the plates being required.

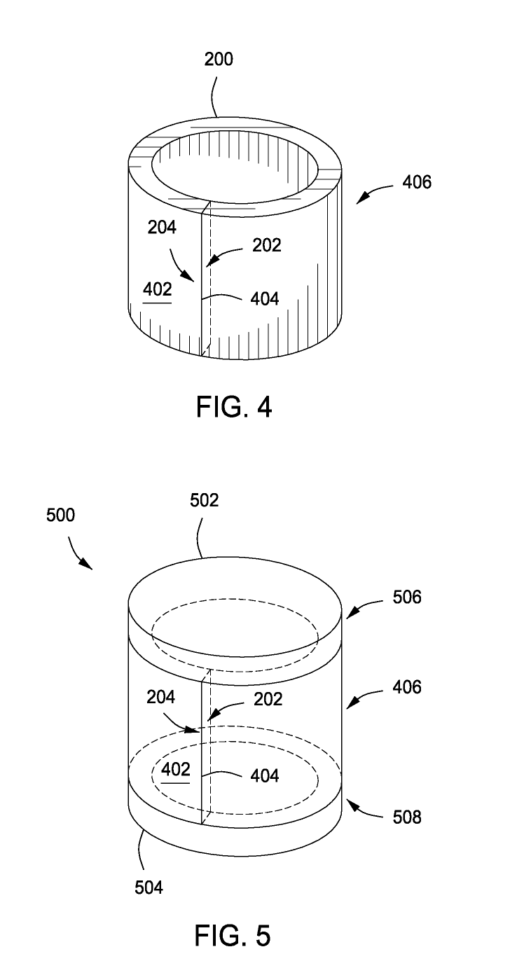

Next, a friction stir weld is performed on outer surfaces of adjacent ends of the one or more plates to form a cylindrical body 406, for example, for use as a portion of the vacuum chamber or of a component of the process chamber. For example, as shown at 106 and in FIG. 4, a friction stir weld is performed to form a body 406 of a vacuum chamber or of a process chamber component. The friction stir weld is performed on an outer surface 402 of one or more ends (e.g., the first end 202 and/or second end 204) of the plate 200 to join the one or more ends together, as shown in FIG. 4. Alternatively, or in combination, in some embodiments friction stir weld is performed to join the one or more ends to ends of an adjacent plate (e.g., where multiple plates are utilized to form a multifaceted chamber or component body, such as described below with respect to FIGS. 8 and 9).

The inventor has observed that a friction stir weld advantageously provides a deeper penetration (e.g., full depth penetration) into the plate 200 and provides a weld having zero or near zero porosity, thereby providing a more secure coupling of the ends of the plate 200 as compared to surface or fillet welds produced in conventional welding processes (e.g., arc or TIG welding) that do not provide such penetration. The lack of porosity advantageously prevents leaks across O-ring seals and prevents virtual leaks due to a trapped volume of gas. In addition, due to the lower temperatures (as compared to conventional welding processes) required to perform a friction stir weld, materials that may not be welded by conventional welding processes (e.g., aluminum) may be welded via a friction stir weld, thus advantageously providing flexibility with respect to the choice of material used to fabricate the vacuum chamber. Moreover, the friction stir weld process facilitates the desired weld without depositing filler material (e.g., flux provided in conventional welding processes) at the weld seam 404, thereby providing a more secure coupling of the ends of the plate 200. Thus, in some embodiments, the ends of the plate 200 may be welded directly together and provide a suitable seal without any additional materials or components covering the weld seam and without flux or other filler material being deposited at the weld seam.

In embodiments where a vacuum chamber is to be formed, next at 108, at least one of a top 502 or bottom 504 is coupled to a respective top 506 or bottom 508 of the body 406 to form the vacuum chamber 500. The at least one of the top 502 or bottom 504 may be coupled to the respective top 506 or bottom 508 of the body 406 via any mechanism suitable to provide vacuum tight coupling of the top 502 and/or bottom 504 to the body 406 while maintaining sufficient structural integrity during normal use of the vacuum chamber 500.

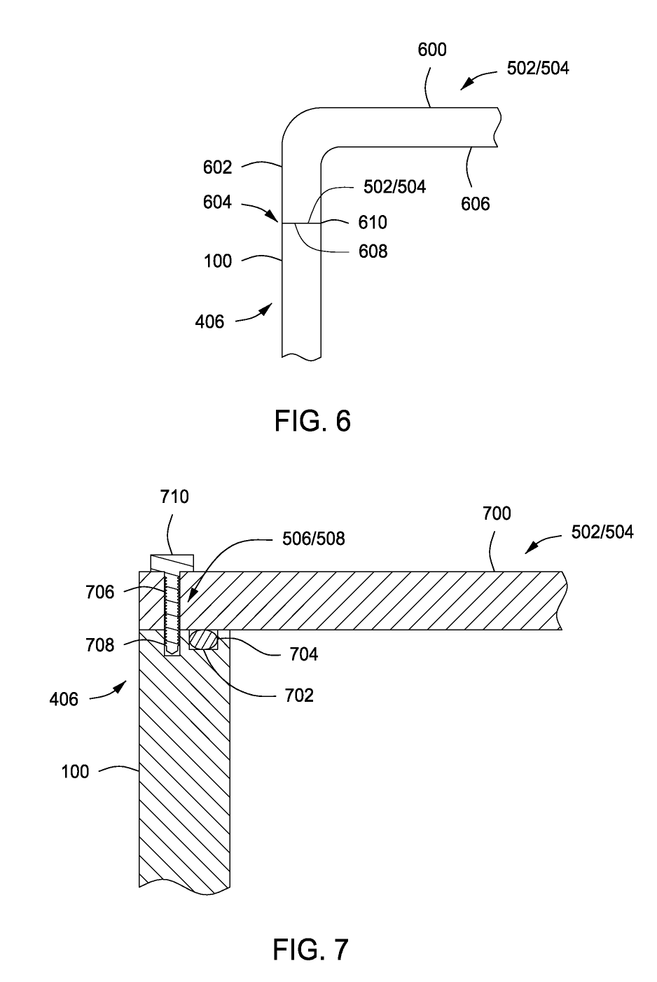

For example, in some embodiments, the top 502 and/or bottom 504 may be coupled to the body 406 via friction stir welding. In such embodiments, each of the top 502 and/or bottom 504 may comprise an upper portion 600 having a ring 602 coupled to, and extending from, a bottom surface 606 of the upper portion 600, such as shown in FIG. 6. The ring 602 may be coupled to the upper portion 600 via any suitable mechanism, for example, such as a brazing, welding (e.g., friction welding), a plurality of fasteners, or the like. Alternatively, in some embodiments, the ring 602 and the upper portion 600 may be fabricated from a single piece of material, thereby providing a unitary component comprising both the upper portion 600 and the ring 602. When utilized, the friction stir weld is performed on an outer surface 604 of the ring 602 and the body 406 at an interface 610 between a bottom surface 608 of the ring 602 and the top 506 and/or bottom 506 and the body 406, thereby coupling the top 502 and/or bottom 504 to the body 406.

Alternatively, in some embodiments, the top 502 and/or bottom 504 may be coupled to the respective top 506 and/or bottom 508 of the body 406 via one or more fasteners (one fastener 710 shown), such as shown in FIG. 7. In such embodiments, the top 502 and/or bottom 504 may comprise an upper portion 700 having one or more through holes 706 formed through the top 502 and/or bottom 504 to allow the fastener 710 to be disposed through the top 502 and/or bottom 504. The fastener 710 may be any type of fastener 710 suitable to couple the top 502 and/or bottom 504 to the body 406, for example, such as a bolt, screw, rivet, or the like. One or more threaded holes (one threaded hole 708 shown) configured to receive the fastener 710 may be disposed in the top 506 and/or bottom 508 of the body 406. In some embodiments, for example where the top 506 or the bottom 508 is fastened to the body 406 via one or more fasteners, a channel 702 to receive a seal 704 (e.g., a gasket, an o-ring, or other suitable material) may be formed in one or more surfaces of the body 406 (as shown) or of the top 506 and/or bottom 508 to facilitate forming a vacuum seal between the body 406 and the top 506 and/or bottom 508 when coupled to one another.

After the at least one of a top 502 or bottom 504 is coupled to the body 406 to form the vacuum chamber 500 at 108, the method generally ends and the vacuum chamber 500 may proceed for further fabrication or configuration depending on the intended use of the vacuum chamber 500 (e.g., processes to be performed in the process chamber). For example, openings for a slit valve door to allow a substrate to be introduced or removed from the chamber, gas inlets, exhaust ports, ports for observation or data gathering, or the like, may be machined into at least one of the body 406, the top 502, or the bottom 504 as required for a particular application.

Although described above as cylindrical body formed from a single plate 200, the body 406 may comprise any number of plates and any shape to fabricate a vacuum chamber suitable for semiconductor substrate processing. For example, in some embodiments, the body 802 may have a hexagonal shape, such as shown in FIG. 8. In such embodiments, the hexagonal body 806 may be formed from two plates (first plate 804 and second plate 806), each bent at three locations (locations 808, 810, 812, 814, 816, 818) along the first plate 804 and the second plate 806. The first plate 804 and the second plate 806 may be coupled to one another via a friction stir weld performed on an outer surface 820, 822 of an interface 824, 826 between the first plate 804 and the second plate 806.

In some embodiments, the hexagonal body 802 may be formed from six plates (plates 828, 830, 832, 834, 836, 838) each bent at one location (locations 808, 810, 812, 814, 816, 818) along the six plates. Each of the six plates may be coupled to an adjacent plate of the six plates via a friction stir weld performed on an outer surface 820, 822, 840, 842, 844, 846 of an interface 824, 826, 846, 848, 850, 852 between adjacent plates of each of the six plates.

In some embodiments, the body 902 may have an octagonal shape, such as shown in FIG. 9. In such embodiments, the octagonal body 902 may be formed from four plates (plates 904, 932, 934, 906), each bent at two locations (locations 908, 910, 912, 914, 916, 918, 920, 922) along the four plates. Each of the four plates may be coupled to an adjacent plate of the four plates via a friction stir weld performed on an outer surface 926, 928, 936, 938 of an interface 940, 942, 944, 946 between adjacent plates of each of the four plates.

In some embodiments, the octagonal body 902 may be formed from eight plates (plates 948, 950, 952, 954, 956, 958, 960, 962) each bent at one location (locations 908, 910, 912, 914, 916, 918, 920, 922) along the eight plates. Each of the eight plates may be coupled to an adjacent plate of the six plates via a friction stir weld performed on an outer surface 926, 928, 936, 938, 964, 966, 968, 970 of an interface 940, 942, 944, 946, 972, 974, 976, 978 between adjacent plates of each of the eight plates.

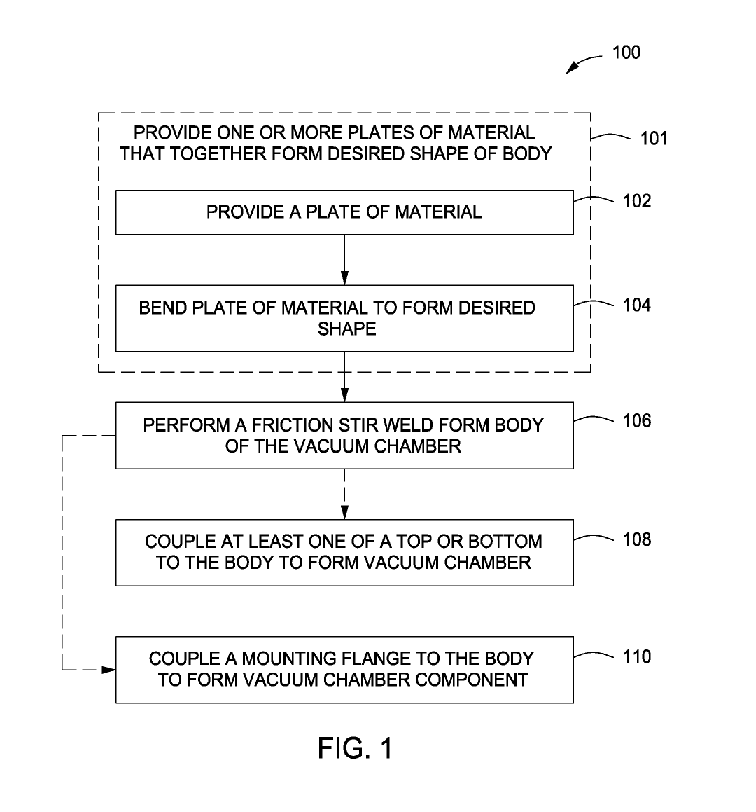

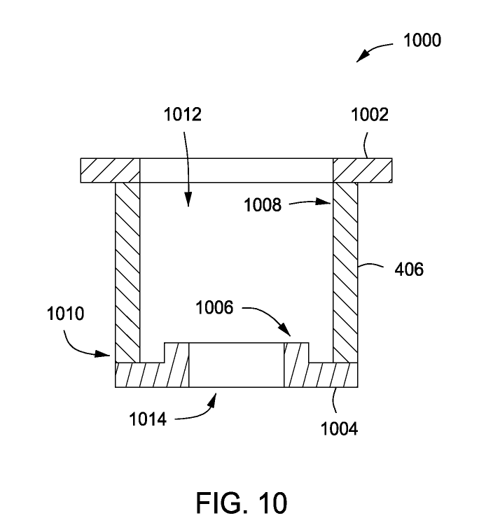

Returning to FIG. 1, in embodiments where a vacuum chamber component is to be formed, the method 100 may skip 108 and proceed to 110, where a mounting flange and optionally other features may be coupled to the body 406 to form the vacuum chamber component. For example, as shown in FIG. 10, the ring-shaped part as shown in FIG. 4 could also be used to form a deposition or process kit shield which is free of fillers or porosity, such as the exemplary process kit shield 1000 depicted in FIG. 10. The process kit shield 1000 includes the body 406. A mounting flange 1002 may be coupled to a top 1008 of the body 406. The mounting flange 1002 extend radially outward from the body 406 and is used to mount the process kit shield 1000 to the process chamber during use. The body 406 (and the mounting flange 1002) fit within a process chamber and have a central opening 1012 corresponding to a processing volume of the process chamber.

Optionally, in some embodiments, a process kit support flange 1004 may be coupled to a bottom 1010 of the body 406. The process kit support flange 1004 extends radially inward and is used to support other process kit components, such as a process kit ring that may surround a substrate during processing. The process kit support flange 1004 may also include an upwardly extending lip 1006. The lip 1006 may provide a support surface for the process kit ring. The process kit support flange 1004 has a central opening 1014 having a diameter larger than a substrate that is to be processed, such that upon positioning the process kit shield 1000 in place above a substrate, the substrate is exposed to the processing volume contained within the central opening 1012 of the process kit shield 1000 and is not covered by the process kit support flange 1004.

Cleaning, texturing, and/or anodizing of the shield 1000 can be performed to finalize the process kit shield 1000 for use. Thus, a porosity-free component can be provided that is compatible with high vacuum processes (e.g., PVD and the like) or where the purity offered by no fillers in the weld is important to prevent fluorine attack (e.g., etch processes).

Thus, embodiments of method for fabricating a vacuum chamber or component have been provided herein. In some embodiments, the inventive method may advantageously facilitate a cost effective method of fabricating vacuum chambers and chamber components having fewer defects, lower porosity and improved structural integrity as compared to conventionally used vacuum chamber fabrication methods.

While the foregoing is directed to embodiments of the present invention, other and further embodiments of the invention may be devised without departing from the basic scope thereof.

1. A method for fabricating a vacuum chamber for semiconductor substrate processing, comprising:
providing one or more plates of material that together form a desired shape of a body of the vacuum chamber;
performing a friction stir weld on outer surfaces of adjacent ends of the one or more plates to form the body of the vacuum chamber; and
coupling at least one of a top or bottom to a respective top or bottom of the body to form the vacuum chamber.

2. The method of claim 1, further comprising:
bending the one or more plates of material to form a desired shape.

3. The method of claim 2, wherein bending the plate of material comprises bending a single plate into a cylindrical shape and wherein performing the friction stir weld comprises friction stir welding a first end of the single plate to a second end of the single plate to form a cylindrical body.

4. The method of claim 2, wherein bending the plate of material comprises bending a first plate at three locations along the first plate and bending a second plate at three locations along the second plate and wherein performing the friction stir weld comprises friction stir welding the first plate to the second plate to form a hexagonal body.

5. The method of claim 2, wherein bending the plate of material comprises bending six plates at one location along each of the six plates and wherein performing the friction stir weld comprises friction stir welding each plate of the six plates to an adjacent plate of the six plates to form a hexagonal body.

6. The method of claim 2, wherein bending the plate of material comprises bending a first plate at four locations along the first plate and bending a second plate at four locations along the second plate and wherein performing the friction stir weld comprises friction stir welding the first plate to the second plate to form an octagonal body.

7. The method of claim 2, wherein bending the plate of material comprises bending four plates at two locations along each of the four plates and wherein performing the friction stir weld comprises friction stir welding each plate of the four plates to an adjacent plate of the four plates to form an octagonal body.

8. The method of claim 2, wherein bending the plate of material comprises bending eight plates at one location along each of the eight plates and wherein performing the friction stir weld comprises friction stir welding each plate of the eight plates to an adjacent plate of the eight plates to form an octagonal body.

9. The method of claim 1, wherein the material is one of aluminum, stainless steel, or steel.

10. The method of claim 1, wherein the at least one of the top or bottom comprises an upper portion and a ring extending from a bottom surface of the upper portion, and wherein coupling at least one of the top or bottom to the respective top or bottom of the body to form the vacuum chamber comprises:
positioning the at least one of the top or bottom on the respective top or bottom of the body such that a bottom surface of the ring is disposed on the respective top or bottom of the body; and
performing a friction stir weld on an outer surface of an interface between the at least one of the top or bottom and to couple the at least one of the top or bottom to the body.

11. The method of claim 1, wherein the at least one of the top or bottom comprises an upper portion and wherein coupling at least one of the top or bottom to the respective top or bottom of the body to form the vacuum chamber comprises:
forming a through hole in a portion of the upper portion to allow a fastener to be disposed through the upper portion;
forming a threaded hole in the at least one of the top or bottom to the body;
positioning the upper portion on the respective top or bottom of the body such that the through hole aligns with the threaded hole; and
providing the fastener to the through hole and the threaded hole to couple the at least one of the top or bottom to the respective top or bottom of the body.

12. The method of claim 11, wherein coupling the at least one of the top or bottom to the respective top or bottom of the body to form the vacuum chamber further comprises:
forming a channel in the respective top or bottom of the body to receive a sealing material; and
disposing the sealing material in the channel.

13. The method of claim 12, wherein the sealing material is an o-ring.

14. The method of claim 12, wherein the sealing material forms a vacuum seal between the body and the at least one of the top or bottom when the at least one of the top or bottom is fully coupled to the body via the fastener.

15. The method of claim 1, wherein the plate of material comprises a rectangular cross section.

16. The method of claim 15, wherein the plate of material has a length of about 20 to about 120 inches.

17. The method of claim 15, wherein the plate of material has a width of about 20 to about 120 inches.

18. The method of claim 15, wherein the plate of material has a thickness of about 0.5 to about 2.0 inches.

19. A method for fabricating a vacuum chamber component for use in a vacuum process chamber, comprising:
providing one or more plates of material that together form a desired shape of a body of the vacuum chamber component;
performing a friction stir weld on outer surfaces of adjacent ends of the one or more plates to form the body of the vacuum chamber component; and
coupling a mounting flange to a top of the body to form the vacuum chamber component.

20. The method of claim 19, further comprising:
coupling an inwardly extending process kit support flange to a bottom of the body.
